(19) United States
(12) Patent Application Publication
(10) Pub. No.: US 2010/0289749 A1
(43) Pub. Date: Nov. 18, 2010

(54) KEY INPUT INTERFACE METHOD

(76) Inventor: Jaewoo AHN, Gyeonggi-do (KR)

Correspondence Address: North Star Intellectual Property Law, PC, P.O. Box 34688, Washington, DC, 20043, US

(21) Appl. No.: 12/675,428

(22) PCT Filed: Aug. 28, 2008
(86) PCT No.: PCT/KR2008/005060

§ 371 Date: Feb. 26, 2010

(30) Foreign Application Priority Data
Aug. 28, 2007 (KR) 10-2007-0086322

(51) Int. Cl. H03M 11/00; G06F 3/02

(52) U.S. Cl. 345/172; 341/23

(57) ABSTRACT

A key input interface method is provided. The key input interface method includes allocating key elements belonging to either a first group or a second group to a key array; and processing a key element allocated to a selected key as input, wherein the key element belonging to either the first group or the second group is identified by distinguishing a key element selection method. Accordingly, a compact electronic device is possible to have various key inputs with a limited number of keys.

### TECHNICAL FIELD

The following description relates to a key input interface method, and more particularly, to a key input interface method which allows various types of inputs by use of only limited number of keys in a compact electronic appliance.

### BACKGROUND ART

With the development of semiconductor technology, mobile terminals including mobile phones and personal digital assistants (PDAs) have been miniaturized and various functions have been increasingly employed enough for the mobile terminals to perform as minicomputers. However, inputting means of such mobile terminals may hinder the miniaturization of the mobile terminals. In the early stage of the mobile terminal technology, letters were almost only data to be input by the inputting means, and hence a limited number of buttons were sufficient for the inputting means to perform the input function. However, in recent days, there arises a need of new inputting means as functional as a keyboard. Accordingly, the conventional art has suggested miniaturization of a keyboard and the connection of the miniaturized keyboard to a mobile terminal, but there is a limit in miniaturization since the keyboard has to be designed in consideration of the user's input, and the conventional method of connecting the keyboard and the mobile terminal causes, consequently, an increase in volume of the mobile terminal.

### DISCLOSURE OF INVENTION

### Technical Problem

It is an object of the present invention to provide a key input interface method for an electronic appliance, and especially, an electronic appliance which does not have a sufficient number of button means in order to reduce in size.

### Technical Solution

A key input interface method is provided to solve technical problems described above. The key input interface method includes allocating key elements belonging to either a first group or a second group to a key array; and processing a key element allocated to a selected key as input, wherein the key element belonging to either the first group or the second group is identified by distinguishing a key element selection method.

In the allocation of the key elements, at least one key element belonging to the first group and at least one key element belonging to the second group may be simultaneously allocated to at least one key.

The key input interface method may further include providing a screen interface for key selection.

Additional features of the invention will be set forth in the description which follows, and in part will be apparent from the description, or may be learned by practice of the invention.

### Advantageous Effects

According to the present invention, a plurality of key elements belonging to a first group and belonging to a second group are simultaneously allocated to each key of a key array having a limited number of keys. Also, interface methods of selecting a key element belonging to a first group and a key element belonging to a second group are differently performed, thereby allowing a compact electronic appliance to perform various types of key input with only a limited number of keys.

In addition, different key selection methods allow key elements belonging to a first group and a second group to be distinguished and selected, and thus a number of key elements are possible to be allocated at one time to a key array having a limited number of keys. As the result, new allocation of key elements in the key array may be prevented when there are new key elements to be input.

The processing of the key element may include selecting a divided region through the screen interface, determining a method of selecting the divided region, and processing the key element as input, wherein the key element is belonging to the first or second group and allocated to a key corresponding to the selected divided region.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a flowchart illustrating a key input interface method according to an exemplary embodiment.

FIG. 2 is an example diagram showing a 3×3 key array in which alpha keys are allocated.

FIG. 3 is an example diagram showing a 3×3 key array in which beta keys are allocated.

FIG. 4 is an example diagram showing a 3×3 key array in which both the alpha keys and the beta keys are allocated thereon together.

FIG. 5 is an example diagram showing a key array in which alpha keys and beta keys are allocated in a text mode.

FIG. 6 is another example diagram showing a key array in which alpha keys and beta keys are allocated in a text mode.

FIG. 7 is another example diagram showing a key array in which alpha keys and beta keys are allocated in a text mode.

FIG. 8 is an example illustration showing positions of a tab key, a bspace key, and a space key on a keyboard.

FIG. 9 is an example diagram showing a key array in which alpha keys and beta keys are allocated in a keyboard mode.

FIG. 10 is another example diagram showing a key array in which alpha keys and beta keys are allocated in a keyboard mode.

FIG. 11 is another example diagram showing a key array in which alpha keys and beta keys are allocated in a keyboard mode.

FIG. 12 is an example illustration showing positions of a ctrl key, a shift key, an alt key, and a win key on a keyboard.

FIG. 13 is an example illustration showing a key map and a gridded screen interface.

FIG. 14 is another example illustration showing a key map and a gridded screen interface.

FIG. 15 is an example illustration showing a gridded screen interface.

FIG. 16 is another example illustration showing a gridded screen interface.

FIG. 17 is an illustration for showing how an alpha key and a beta key are selected by a touch and a stroke.

FIG. 18 is an example illustration showing changes in a stroke direction.

FIG. 19 is an illustration for showing how an alpha key and a beta key are selected by a touch and a directional stroke.

FIG. 20 is an illustration for showing how an alpha key and a beta key are selected by a single-touch and a double-touch.

FIG. 21 is an illustration for showing how an alpha key and a beta key are selected by a multi-touch and a multi-stroke.

FIG. 22 is an illustration for showing how an alpha key and a beta key are selected by a multi-touch and a directional stroke.

FIG. 23 is an illustration for showing how an alpha key and a beta key are selected by a multi-touch and a directional stroke.

FIG. 24 is an illustration for showing how an alpha key and a beta key are selected by a multi-touch and a multi-directional stroke.

FIG. 25 is an illustration for showing how an alpha key and a beta key are selected by a single touch/single directional stroke and a double-touch/double-directional stroke.

### MODE FOR THE INVENTION

The invention is described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

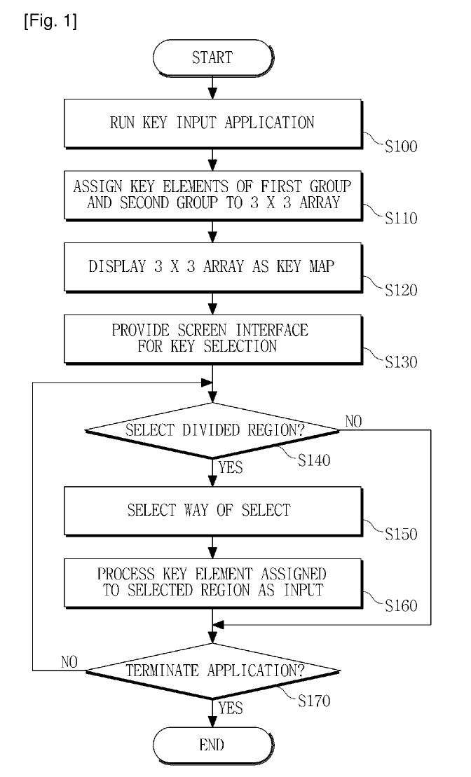

FIG. 1 is a flowchart illustrating a key input interface method according to an exemplary embodiment.

A key input interface application in accordance with an exemplary embodiment is implemented in an electronic device. Examples of the electronic device may include a mobile phone, a personal digital assistant (PDA), a smart phone, and the like. When the key input interface application implemented on the electronic device is operated (operation S100), key elements are allocated to a key array. The key array includes a limited number of keys which are categorized into a first group and a second group (operation S110). In the exemplary embodiment, keys are arranged in a matrix form, for example, a form of 33 (three columns and three rows). However, the key array may have a variety of forms. The key elements may be divided into the first and second groups according to their properties, but the criteria are not limited to the properties. However, the method of categorizing the key elements does not fall within the scope of the present invention.

In operation S110, some of matrix keys have allocated thereto both key elements belonging to the first group and belonging to the second group. Also in operation S110, a plurality of key elements belonging to the first group may be allocated to a matrix key, and a plurality of key elements belonging to the second group may be allocated to a matrix key. Hereinafter, the key elements belonging to the first group will now be referred to as alpha ( ) keys and ones belonging to the second group will be referred to beta ( ) keys.

A matrix having the alpha keys and the beta keys arranged thereon is displayed as a key map (operation S120). A user inputs an alpha key or a beta key with reference to the key map. A screen interface is provided for key selection by dividing at least a part of a screen into three columns and three rows and using the whole divided part as the screen interface (operation S130). In addition, if necessary, for example, if a user request is input through a user interface, grid lines are displayed for dividing the entire area of the screen so that the user can directly and clearly recognize divided regions.

When a user selects any of the divided regions, it is determined how the user selects the corresponding region (operations S140 and S150). Examples of methods of selecting a divided region may vary and include, for example, touching or stroking of the screen. Once the selecting method is determined, an alpha key input or a beta key input is processed on a key corresponding to a divided region, which is selected according to the determined selecting method, (operation S160). For example, if the divided region is selected by a touch, an alpha key is processed as input to a key on the selected region, and if the divided region is selected by a stroke, a beta key is processed as input to a key corresponding to the selected region.

The key input interface in accordance with the exemplary embodiment provides a text mode and a keyboard mode. The text mode allows input of general letters, numbers and symbols, and the keyboard mode allows input of special letters besides the general characters, numbers and symbols. The mode shifts between the text mode and the keyboard mode by a key input. In each mode, key elements to be used according to key inputs may be newly allocated to enable a variety of key inputs. In this regard, Korean patent application No. 10-2006-135001, filed by the present inventor on Dec. 27, 2006, discloses allocation of new key elements in detail.

In operation S160 where the alpha key and beta key are input and processed, activities are performed according to the nature of the corresponding key element, a mode is shifted, or new key allocation takes place in the current mode.

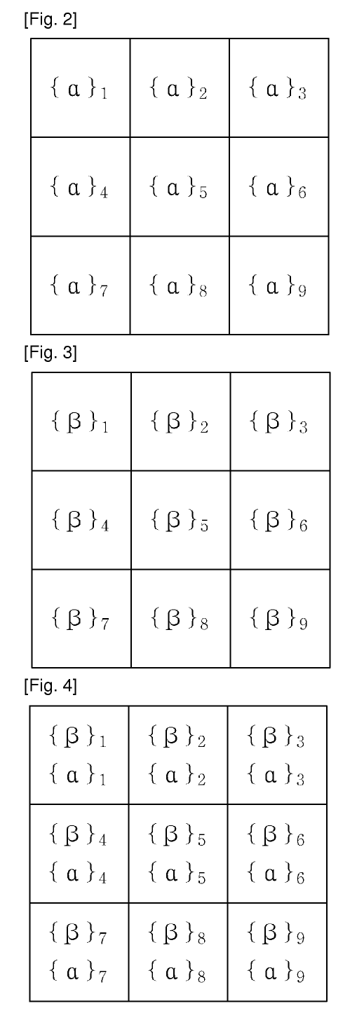

FIG. 2 is an example diagram showing a 3×3 key array in which alpha keys are allocated, FIG. 3 is an example diagram showing a 3×3 key array in which beta keys are allocated, and FIG. 4 is an example diagram showing a 3×3 key array in which both the alpha keys and the beta keys are allocated thereon. The present description provides a technical solution that allows distinguishing and selecting between the alpha and beta keys even when both alpha and beta keys are allocated together as shown in FIG. 4. Each letter and in braces, { } and { }, indicates that a plurality of alpha keys and a plurality of beta keys can be allocated in each region of the array.

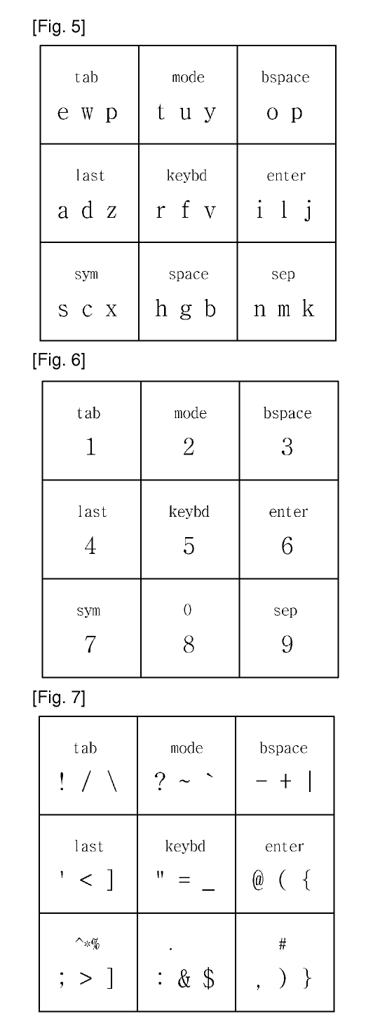

FIGS. 5 to 7 are example diagrams showing a 3×3 array in which alpha keys and beta keys are allocated in a text mode.

In a text mode, key elements to be categorized into alpha keys and beta keys are allocated to the same key. Furthermore, referring to FIGS. 5 and 7, it can be noted that a plurality of alpha keys are possible to be allocated to a single key, and referring to the first column in the third row of FIG. 7, it can be understood that a plurality of beta keys also can be allocated to a single key.

Referring to FIGS. 5 to 7, key elements, such as tab, bspace, enter, and space key elements, are firmly allocated constantly. Also the locations of such key elements are fixed. For information, Bspace in drawings denotes a backspace key. Since key elements described above are frequently used in a text mode, they may be consistently allocated to corresponding keys even when key elements are newly allocated in a text mode.

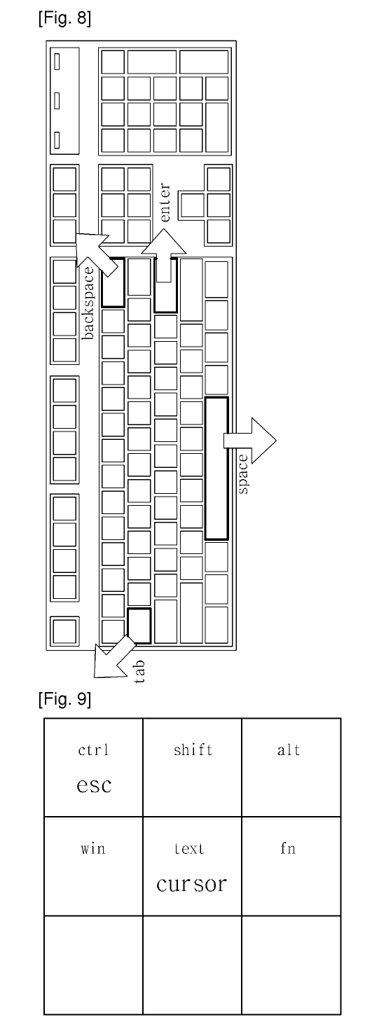

In addition, it may be desirable to allocate the key elements in a 3×3 array in consideration of the positions of keys on a keyboard. As shown in FIG. 8, a ‘tab’ key is located at the left upper side, a ‘bspace’ key is located at the right upper side, an ‘enter’ key is located at the right side, and a ‘space’ key is located at the bottom of a keyboard, and in consideration of such positions of the keys, the key elements are allocated corresponding to the arrangement of the keys on the keyboard.

Referring to FIGS. 5 to 7, a key element ‘keybd’ is firmly allocated in a text mode. The ‘keybd’ element is for shifting the mode from a text mode to a keyboard mode, and may be located at the second column in the second row of the key array.

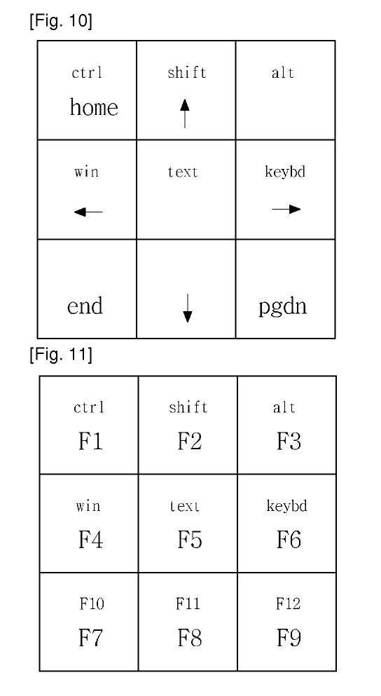

FIGS. 9, 10, and 11 are example diagrams illustrating a 3×3 array in which alpha and beta keys are allocated in a keyboard mode.

Like in a text mode, key elements to be categorized into alpha keys and beta keys are possible to be allocated together to the same key. Furthermore, although not illustrated in drawings, like in the text mode, either of a plurality of alpha keys or a plurality of beta keys may be allocated to a single key.

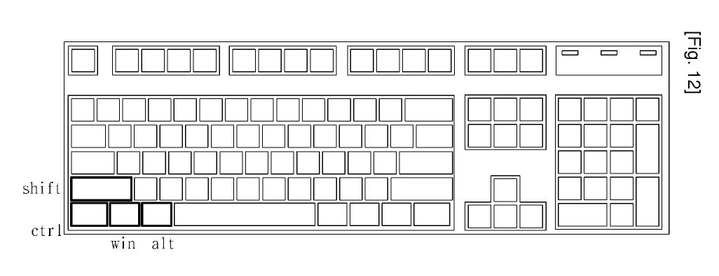

Referring to FIGS. 9 to 11, it is noted that key elements of ‘ctrl’, ‘shift’, ‘alt’, and ‘win’, which are referred to as modifier key elements, are consistently allocated to a key array in a keyboard mode. Also, the positions of these key elements are fixed on the key array. Since such modifier keys are used frequently in the keyboard mode, it may be desirable that these keys are firmly located at fixed positions even when key elements are newly allocated to the keyboard in keyboard mode. In addition, such key elements may include all kinds of modifier key elements as shown in FIG. 12. For example, one keyboard may have an option key instead of a win key, and may have any other modifier keys.

It is also noted that a ‘text’ key element is firmly allocated to the key array in the keyboard mode. The ‘text’ key element is used for shifting a mode from a keyboard mode to a text mode, and may be located at the second column in the second row of the key array.

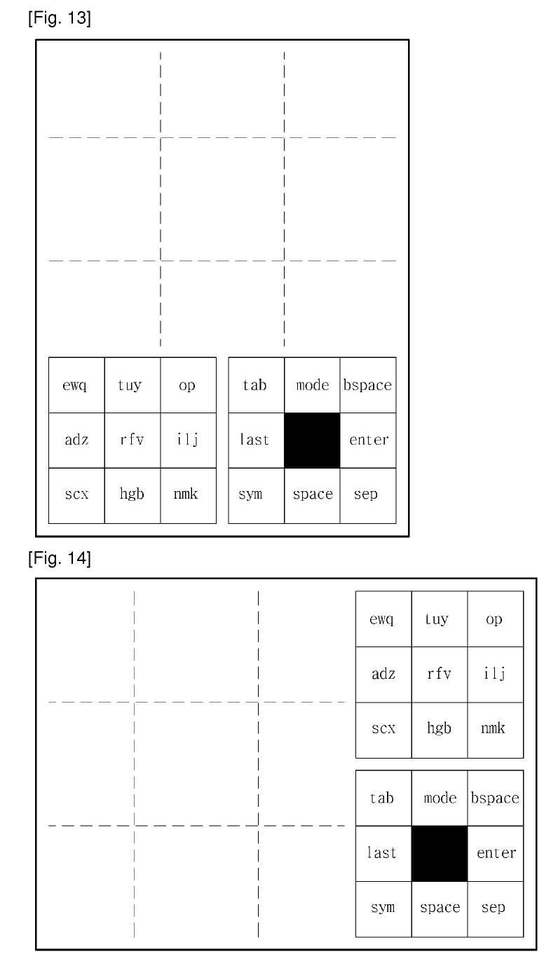

FIGS. 13 and 14 are example diagrams illustrating a key map and a gridded screen interface.

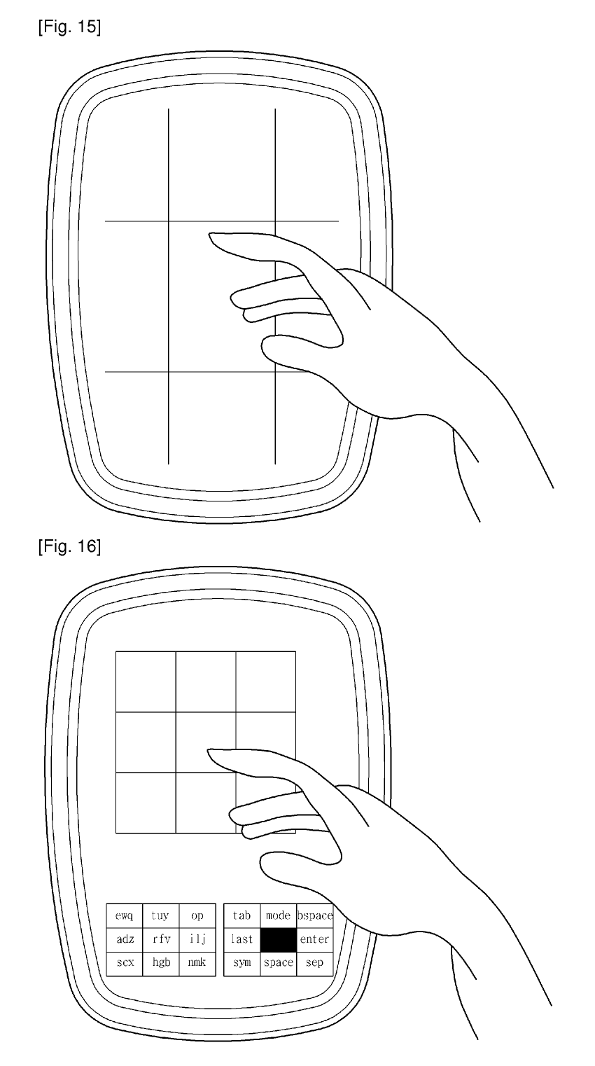

As shown in FIGS. 13 and 14, alpha key arrangement and beta key arrangement which function as a key map are positioned at either of the right side or the bottom of a screen and the screen is evenly divided by three columns and three rows to create the gridded screen interface. By the use of the key map and the gridded screen interface, a user selects an alpha key or a beta key to be input. The screen area excluding an area for a key map is evenly divided by three rows and three columns to create a screen interface, but the division of the screen is not limited to a 3×3 array. For example, when there is no key map displayed, the entire screen can be evenly partitioned by three columns and three rows as shown in FIG. 15, or alternatively a part of the screen is evenly divided by three columns and three rows as shown in FIG. 16.

There will be described below various embodiments of methods of selecting alpha keys and beta keys and of determining how to select the keys.

### FIRST EXEMPLARY EMBODIMENT

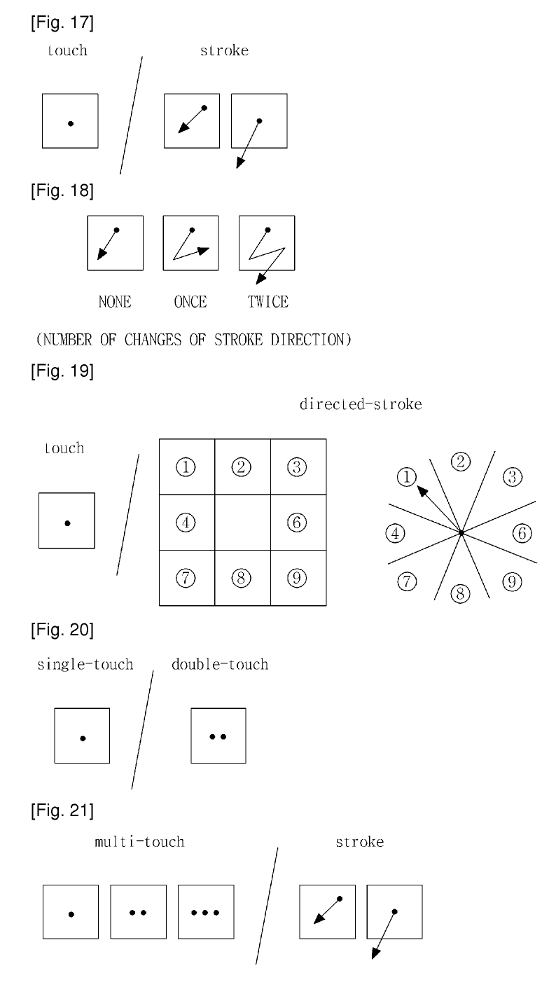

As shown in FIG. 17, a region of a screen interface is selected by either touch or stroke. If there is a touch on a screen interface, it is determined that an alpha key is to be selected, and if there is a stroke on the screen interface, it is determined a beta key is to be selected. Additionally, it is defined that a divided region of a key array is selected by being directly touched or stroked. In this case, the stroke may be recognized by observing whether the length of a touch on a divided region is greater than a pre-determined length in a certain direction. In other words, the length of the touch is determined by coordinates of a starting point and an end point of the touch, and if the length of the touch is greater than a predetermined length, the touch is defined as a stroke.

If a divided region of the first column in the first row is touched in the gridded screen interface, the location of the region is identified by detecting the touch and the coordinates of the touched point, and then, an alpha key allocated to the identified region is processed as input. In addition, when a divided region of the first column in the second row is stroked, the location of the region is identified by detecting the stroke and the coordinates of the starting point of stroking, and then, a beta key allocated to the identified region is processed as input.

Referring to FIG. 5 again, when a plurality of alpha keys are allocated to the same region of a key array, it is detected how many times the region is touched consecutively within a predetermined duration of time so that it can be identified which alpha key is selected. For example, it is determined that a letter ‘e’ is selected when the first column in the first row of the key array is touched once, it is determined that a letter ‘w’ is selected when the same region is touched twice within a given duration of time, and it is determined that a letter ‘q’ is selected when the same region is touched three times within a given duration of time. In such a manner, a corresponding alpha key is processed as input. When a plurality of beta keys are allocated to the same region of a key array, it can be detected which beta key is selected by detecting the number of times of stroking the region within a given duration of time or the number of times of changing a direction of a stroke. For example, as shown in FIG. 18, when there is no change in a stroke direction, the first beta key is selected, when a direction of a stroke is changed once, a second beta key is selected, and when a direction of a stroke is changed twice, a third beta key is selected.

### SECOND EXEMPLARY EMBODIMENT

As shown in FIG. 19, a region of a screen interface is selected by a touch or a directional stroke. When there is a touch on the gridded screen interface, it is determined that an alpha key is selected, and when there is a directional stroke, it is determined that a beta key is selected. A divided region of the screen interface is selected by a direct touch, or alternatively the divided region is identified by a direction of a stroke. The direction of the stroke may be identified by coordinates of a starting point and an end point of stroking.

When there is a stroke input on the gridded screen interface, the stroke input is detected and a direction of the stroke is identified by coordinates of a starting point and an end point of the stroke on the interface. From the identified direction, a selected region of the key array on the gridded screen interface is detected, and a beta key allocated to the corresponding region is processed as input. For example, a left upward stroke indicates a region of the first column in the first row is selected, a straight upward stroke indicates a region of the second column in the first row is selected, a right upward stroke indicates a region of the third column in the first row is selected, a stroke to the left indicates a region of the first column in the second row is selected, a stroke to the right indicates a region of the third column in the second row is selected, a stroke of the right indicates a region of the third column in the second row is selected, a left downward stroke indicates a region of the first column in the third row is selected, a straight downward stroke indicates a region of the second column in the third row is selected, and a right downward stroke indicates a region of the third column in the third row is selected. Then, a beta key allocated to the selected region is processed as input.

Unlike the first exemplary embodiment, a directional stroke in accordance with the present embodiment is not limited to the divided regions where the stroke is made. In addition, although it is illustrated that the stroke is made from the center in FIG. 19, it is a merely an example of the position from which the stroke may begin, and the starting point of the directional stroke is not limited thereto. Therefore, a method using the directional stroke allows a user to make a stroke freely in a screen interface as he or she wants. Such characteristic of the directional stroke method may be beneficial in compact electronic appliances with a small screen interface.

In the second exemplary embodiment, like in the first exemplary embodiment, it can be determined which a alpha or a beta key is selected from among a plurality of alpha or beta keys by detecting the number of consecutive touching of a given region within a predetermined duration of time, the number of strokes, or the number of times of changing the stroke direction.

### THIRD EXEMPLARY EMBODIMENT

As shown in FIG. 20, a region of a screen interface is selected by a single-touch or a double-touch. The double-touch refers to a motion that touches two spots simultaneously. When there is a single-touch, it is determined that an alpha key is selected, and when there is a double-touch, it is determined that a beta key is selected.

In such screen interface, when a region of the third column in the second row is selected by a single-touch, the selection of the region is recognized and the coordinates of the touched spot are detected, and then an alpha key allocated to the selected region is processed as input. Alternatively, when a region of the third column in the second row is selected by a double-touch, touches of two spots are sensed and barycenter coordinates of the two spots are calculated from the coordinates of each spot. Then it is determined that the barycenter is placed in the region of the third column in the second row, and based on the position of the barycenter, it is identified that the region of the third column in the second row is selected. Consequently, a beta key allocated to the selected region is processed as input. The barycenter is calculated because the size of a divided region of the key array may be too small to have sufficient room for the double-touch to be made simultaneously. This is because even when a single-touch or a double-touch may miss a desired region to be selected, the barycenter coordinates are highly likely to be placed in a desired region to be selected.

When a plurality of alpha keys are allocated to a single key, one of alpha keys may be recognized based on the number of consecutive single-touches within a predetermined duration of time. In a similar way, when a plurality of beta keys are allocated to a single key, one of beta keys may be recognized based on the number of consecutive double-touches within a predetermined duration of time.

### FOURTH EXEMPLARY EMBODIMENT

As shown in FIG. 21, a region of a screen interface is selected by a multi-touch or a stroke. The multi-touch refers to a motion that touches more than one spot simultaneously. Additionally, the multi-touch is defined as a motion for selecting an alpha key, and a stroke is defined as a motion for selecting a beta key.

In such interface method according to the present embodiment, for example, when there is a multi-touch input to a region of the first column in the third row, spots touched simultaneously are detected and barycenter coordinates of touched spots are calculated. Then, a region where the barycenter is located is identified, one of alpha keys allocated to the corresponding region is recognized based on the number of touches, and then the recognized alpha key is processed as input. The stroke is processed as input by the same procedures as described in the first exemplary embodiment.

### FIFTH EXEMPLARY EMBODIMENT

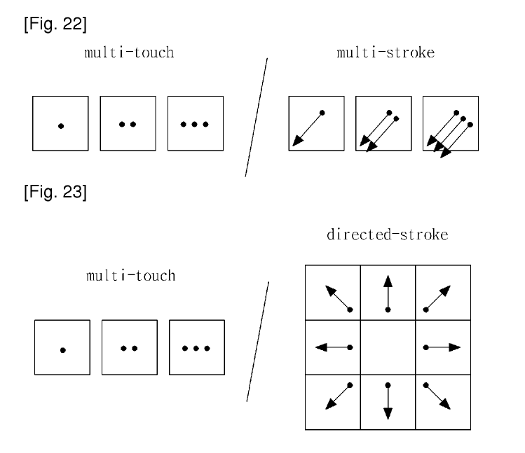

As shown in FIG. 22, a region of a screen interface is selected by either multi-touch or multi-stroke. The multi-touch is defined as a motion for selecting an alpha key and the multi-stroke is defined as a motion for selecting a beta key. The multi-stroke refers to a case where more than one stroke takes place at the same time.

In such interface method, when there is a multi-stroke input, the number of simultaneous strokes is obtained and barycenter coordinates of coordinates of starting points of each stroke are calculated. Based on the barycenter coordinates, the selected region is identified, and one of beta keys allocated to the selected region is processed as input, wherein the beta key to be processed is identified based on the number of strokes. The multi-touch is processed as input by the same procedures as described in the fourth exemplary embodiment.

### SIXTH EXEMPLARY EMBODIMENT

As shown in FIG. 23, a region of a screen interface is selected by either a multi-touch or a directional stroke. The multi-touch is defined as a motion for selecting an alpha key and the directional stroke is defined as a motion for selecting a beta key. In the present embodiment, the multi-touch input is processed by the same procedures described in the fourth exemplary embodiment, and the directional stroke input is processed by the same procedures described in the second exemplary embodiment.

### SEVENTH EXEMPLARY EMBODIMENT

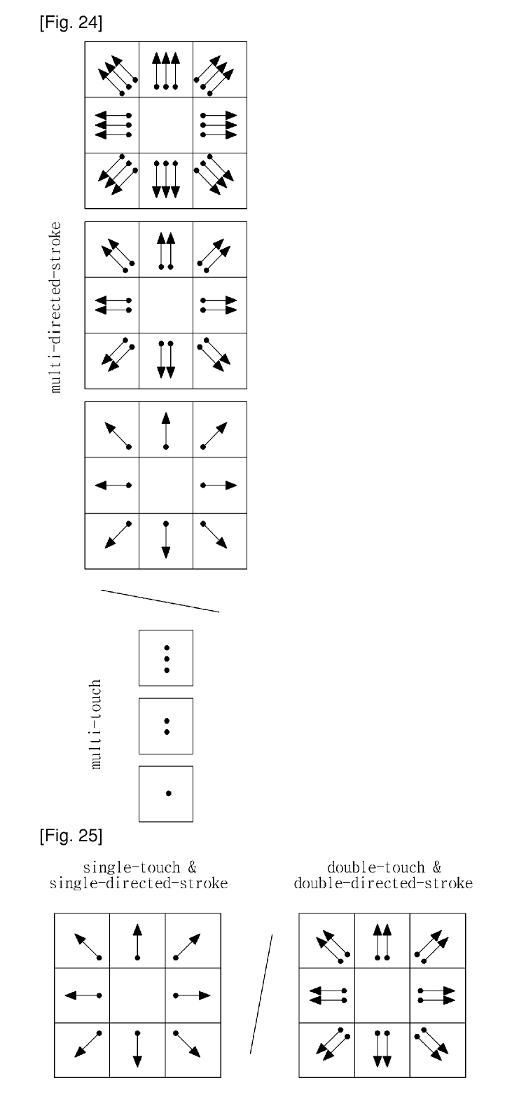

As shown in FIG. 24, a region of a screen interface is selected by either a multi-touch or a multi-directional stroke. The multi-touch is defined as a motion for selecting an alpha key, and the multi-directional stroke is defined as a motion for selecting a beta key.

In the present embodiment, when there is a multi-directional stroke input, the number of simultaneous strokes and a direction of strokes are detected. By the detection results, it is identified which region is selected, and one of beta keys allocated to the identified region is processed as input. The beta key to be processed is determined based on the number of strokes. During this course, the multi strokes have the same direction, and thus a direction of the strokes can be recognized by use of coordinates of a starting point and an end point of any of the strokes. In alternative, a direction of the strokes can be identified by changes in directions of barycenter of each touching point of the stroke. In the present exemplary embodiment, the multi-touch input is processed by the same procedures described in the fourth exemplary embodiment.

### EIGHTH EXEMPLARY EMBODIMENT

As shown in FIG. 25, a region of a screen interface is selected by either a single-touch/single directional stroke or a double-touch/double directional stroke. The single touch/single directional stroke is defined as a motion for selecting an alpha key, and the double touch/double directional stroke is defined as a motion for selecting a beta key.

When a certain region is touched, it is determined if the touch is a single touch or a double-touch. If the touch is determined as a single-touch, an alpha key allocated to a region of the second column in the second row is processed as input, or otherwise if the touch is determined as a double-touch, a beta key allocated to the second column in the second row is processed as input. Moreover, if a certain region is stroked, it is determined if the stroke is a single-stroke or a double-stroke, and a direction of the stroke is detected. When the stroke is determined as a single-stroke, an alpha key allocated to any region, other than a region of the second column in the second row, corresponding to the direction of the stroke is processed as input. When the stroke is determined as a double-stroke, a beta key allocated to the region is processed as input.

A direction of the stroke determines a key location. For example, a left upward stroke indicates a key at the first column in the first row, a straight upward stroke indicates a key at the second column in the first row, a right upward stroke indicates a key at the third column in the first row, a stroke to the left indicates a key at the first column in the second row, a stroke to the right indicates a key at the third column in the second row, a left downward stroke indicates a key at the first column in the third row, a straight downward stroke indicates a key at the second column in the third row, and a right downward stroke indicates a key at the third column in the third row.

### NINTH EXEMPLARY EMBODIMENT

Different inputs by an input device are distinguished to identify an alpha key and a beta key. Examples of such input device include a mouse with left and right buttons, and a stylus pen having a penpoint and side buttons. When a divided region of a screen interface is clicked with a left button of a mouse, it is determined that an alpha key allocated to a key corresponding to clicked region is selected, and when the region is clicked with a right button of the mouse, it is determined that a beta key allocated to the key corresponding to the clicked region is selected. For another example, when a certain region is touched with a penpoint of a stylus pen, it is determined that an alpha key is selected, and in alternative when the region is touched while a side button of the stylus pen is being pressed, it may be determined that a beta key allocated to a key corresponding to the selected region is selected and then the beta key is processed as input. Furthermore, based on the number of consecutive touches on a given region within a predetermined duration of time, it is determined that either one of alpha or beta keys is selected, which is allocated to a key corresponding to the selected region.

### TENTH EXEMPLARY EMBODIMENT

Like in ninth exemplary embodiment, in the present embodiment, different inputs by an input device are distinguished to identify an alpha key and a beta key. When a touch input is made to a screen interface with the left button of a mouse or a penpoint of a stylus pen, it is determined that an alpha key allocated to the region of the second column in the second row of the screen interface is selected, and when a touch input is made to a screen interface with the right button of a mouse or a penpoint of a stylus with its side button pressed, it is determined that a beta key allocated to the region of the second column in the second row is selected. When a stroke input is made to the screen interface with the left button of a mouse or a penpoint of a stylus, an alpha key allocated to one of keys excluding a key of the second column in the second row of the screen interface is processed as input according to a direction of the stroke, and when a stroke input is made to the screen interface with the right button of a mouse or a penpoint of a stylus with a side button being pressed, a beta key allocated to one of keys excluding a key of the second column in the second row is processed as input.

### ELEVENTH EXEMPLARY EMBODIMENT

In the present exemplary embodiment, a method of identifying an alpha key and a beta key by using an auxiliary key besides a 3×3 array. Here, the auxiliary key functions as a ‘shift’ key of a keyboard. That is, when there is a selection by a touch without pressing the auxiliary button, it is determined that an alpha key allocated to a selected key is selected, and the selected alpha key is processed as input. When a touch input is made while the auxiliary key is being selected, it is determined that a beta key allocated to a selected key is selected, and the selected beta key is processed as input. Furthermore, a key element from among the same type of key element allocated to the selected key is identified based on the number of touches within a predetermined duration of time. Then, the identified key element is processed as input.

### TWELFTH EXEMPLARY EMBODIMENT 2

In the present exemplary embodiment, an alpha key and a beta key are distinguished by use of the duration of touch. If the duration of touch is less than a predetermined value, it is determined that an alpha key is selected, and if the duration of touching is greater than the predetermined value, it is determined that a beta key is selected. Moreover, a key element is identified based on the number of touches within a pre-determined duration of time, from among the same type of key elements allocated to a selected key.

### THIRTEENTH EXEMPLARY EMBODIMENT

In the present exemplary embodiment, an alpha key and a beta key are distinguished from each other based on intensity of touch. When intensity of touch is less than a pre-determined value, it is determined that an alpha key is selected, and if the intensity of touch is greater than the predetermined value, it is determined that a beta key is selected. Moreover, a key element is identified based on the number of touches within a predetermined duration of time, from among the same type of key elements allocated to a selected key.

The invention can also be embodied as computer readable codes on a computer readable recording medium. The computer readable recording medium is any data storage device that can store data which can be thereafter read by a computer system. Examples of the computer readable recording medium include read-only memory (ROM), random-access memory (RAM), CD-ROMs, magnetic tapes, floppy disks, optical data storage devices, and carrier waves.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

1. A key input interface method comprising:
allocating key elements belonging to either a first group or a second group to a key array; and
processing a key element allocated to a selected key as input, wherein the key element belonging to either the first group or the second group is identified by distinguishing a key element selection method.

2. The key input interface method of claim 1, wherein the key array is in a matrix form.

3. The key input interface method of claim 1, wherein in the allocation of the key elements, at least one key element belonging to the first group and at least one key element belonging to the second group are simultaneously allocated to at least one key.

4. The key input interface method of claim 3, wherein in the allocation of key elements, by processing a key element, new key elements belonging to either a first group or a second group are allocated to at least some of the keys replacing the currently allocated key elements.

5. The key input interface method of claim 4, wherein in the allocation of key elements, at least some of the key elements belonging to the second group are firmly allocated to the key array.

6. The key input interface method of claim 5, wherein at least some of the key elements are firmly allocated to the key array for a text mode in which text inputs including letters, numbers and symbols are made and the key elements include at least one of a tab key element, a backspace key element, an enter key element, and a space key element.

7. The key input interface method of claim 6, wherein the key array is in a form of three columns and three rows, and the tab key element is allocated to the first column in the first row, the backspace key element allocated to the third column in the first row, the enter key element allocated to the third column in the second row, the space key element allocated to the second column in the third row.

8. The key input interface method of claim 5, wherein at least some of the key elements are firmly allocated to the key array for a keyboard mode supporting inputs the same as keyboard inputs and the key elements include at least one of a ctrl key element, a shift key element, an alt key element, and a window key element, which correspond to modifier keys of a keyboard.

9. The key input interface method of claim 8, wherein the key array is in a form of three columns and three rows, and the ctrl key element is allocated to the first column in the first row, the shift key element allocated to the second column in the first row, and the alt key element allocated to the third column in the first row.

10. The key input interface method of claim 5, wherein a mode shift key is firmly disposed at the second column in the second row in the key array, which enables mode shift between a text mode and a keyboard mode.

11. The key input interface method of claim 3, further comprising:
displaying the key array to which the input key elements are allocated.

12. The key input interface method of claim 3, further comprising:
providing a screen interface for key selection.

13. The key input interface method of claim 12, wherein in the providing of the screen interface, at least a part of a screen is divided to be same as the key array and the whole divided area is provided for the screen interface for key selection.

14. The key input interface method of claim 13, wherein in the providing of the screen interface, grid lines that divide the whole area of the screen interface are displayed in a screen.

15. The key input interface method of claim 13, wherein the processing of the key element comprises selecting a divided region through the screen interface, determining the selection method of the divided region, and processing the key element as input, wherein the key element is belonging to the first or the second group and allocated to the key corresponding to the selected divided region.

16. The key input interface method of claim 15, wherein in the determining the selection method of the divided region, it is determined whether a touch or a stroke is used to select the divided region.

17. The key input interface method of claim 16, wherein in the processing of the key element, when it is determined that a touch is used to select the divided region, one of the key elements belonging to the first group and allocated to the key corresponding to the selected divided region is processed as input, wherein the selected key element is corresponding to the number of touches within a predetermined duration of time.

18. The key input interface method of claim 16, wherein in the processing of the key element, when it is determined that a stroke is used to select the divided region, one of the key elements belonging to the second group and allocated to the key corresponding to the selected divided region is processed as input, wherein the selected key element is corresponding to the number of strokes within a predetermined duration of time.

19. The key input interface method of claim 16, wherein in the processing of the key element, when it is determined that a stroke is used to select the divided region, one of the key elements belonging to the second group and allocated to the key corresponding to the selected divided region is processed as input, wherein the selected key element is corresponding to the number of direction changes of connected strokes.

20. The key input interface method of claim 16, wherein the processing of the key element comprises: when it is determined that a stroke is used to select a divided region, determining the divided region as the selected divided region where the starting point of the stroke is located, and processing a key element belonging to the second group allocated to the key corresponding to the determined divided region.

21. The key input interface method of claim 16, wherein the processing of the key element comprises: when it is determined a stroke is used to select a divided region, detecting the direction of the stroke, determining which divided region is selected based on the detected direction of the stroke, and processing one of the key elements belonging to the second group allocated to the key corresponding to the determined divided region.

22. The key input interface method of claim 21, wherein the key array is in a form of three columns and three rows, and in the determining of a divided region, when a left upward stroke is detected, it is determined the divided region of the first column in the first row is selected, when a straight upward stroke is detected, it is determined the divided region of the second column in the first row, when a right upward stroke is detected, it is determined the divided region of the third column in the first row, when a stroke to the left is detected, it is determined the divided region of the first column in the second row, when a stroke to the right is detected, it is determined the divided region of the third column in the second row is selected, when a left downward stroke is detected, it is determined the region of the first column in the third row, when a straight downward stroke is detected, it is determined the divided region of the second column in the third row, and when a right downward stroke is detected, it is determined the divided region of the third column in the third row.

23. The key input interface method of claim 15, wherein in the processing of the key element, when the determined key selection method is a single-touch, a key element is processed as input wherein the key element is belonging to the first group allocated to the key corresponding to the selected divided region, and when a determined key selection method is a double-touch in which two touches occur at different spots simultaneously, a key element is processed as input wherein the key element is belonging to the second group allocated to the key corresponding to the selected divided region.

24. The key input interface method of claim 23, wherein the processing of the key element comprises calculating the barycenter of the two touched points when the determined key selection method is a double-touch and determining the region where the barycenter is located as the selected divided region.

25. The key input interface method of claim 16, wherein in the processing of the key element, when a determined key selection method is multi-touch occurred simultaneously, a key element is processed as input, wherein the processed key element is belonging to the first group allocated to the key corresponding to the selected divided region.

26. The key input interface method of claim 25, wherein the processing of the key element comprises calculating the barycenter of the multiple touched points if a divided region of the screen interface is selected by a multi-touch and determining the region where the barycenter is located as the selected divided region.

27. The key input interface method of claim 25, further comprising:
if a divided region of the screen interface is selected by a single-stroke, determining the divided region where the starting point of the single stroke is placed as the selected divided region; and
processing a key element as input, wherein the key is belonging to the second group allocated to the key corresponding to the selected divided region.

28. The key input interface method of claim 25, wherein in the processing of the key element, when a divided region of the screen interface is selected by a multistroke occurring simultaneously, a key element is processed as input wherein the key element is belonging to the second group allocated to the key corresponding to the selected divided region and is corresponding to the number of simultaneous strokes.

29. The key input interface method of claim 28, wherein the processing of the key element comprises calculating the barycenter of the starting points of the multistrokes if a divided region of the screen interface is selected by multi-strokes made simultaneously and determining the region where the barycenter is located as the selected divided region.

30. The key input interface method of claim 25, wherein the processing of the key element comprises detecting the direction of a single stroke when a key is selected by a single stroke, identifying a selected divided region based on the detected direction of the single stroke, and processing a key element as input wherein the key element is belonging to the second group allocated to the key corresponding to the identified divided region.

31. The key input interface method of claim 25, wherein the processing of the key element comprises detecting the direction of multi-strokes when a key is selected by multi-strokes, identifying a selected divided region based on the detected direction of multi-strokes, and processing a key element as input wherein the key element is belonging to the second group allocated to the key corresponding to the identified divided region and is corresponding to the number of simultaneous strokes.

32. The key input interface method of claim 15, wherein the key array is in a form of three columns and three rows, and the processing of the key element comprises, processing as input a key element belonging to the first group allocated to the second column in the second row of the key array when a key is selected by a single-touch, and processing as input a key element belonging to the first group allocated to one of the keys other than the key in the second column in the second row based on the detected direction of the single-stroke when a key is selected by a single-stroke.

33. The key input interface method of claim 32, wherein the processing of the key element comprises processing as input a key element belonging to the second group allocated to the second column in the second row of the key array when a key is selected by a double-touch, and processing as input a key element belonging to the second group allocated to a key corresponding to one of the keys other than the key in the second column in the second row being identified based on the direction of the double-stroke when a key is selected by a doublestroke.

34. The key input interface method of claim 15, wherein in the processing of the key element, when it is determined that there is a touch input from a first input unit of a device, which has at least two input units, a key element is processed as input, wherein the key element is belonging to the first group allocated to the key corresponding to the divided region selected by the touch, and when it is determined that there is a touch input from a second input unit of the device, a key element is processed as input, wherein the key element is belonging to the second group allocated to the divided region selected by the touch.

35. The key input interface method of claim 15, wherein in the processing of the key element, when it is determined that there is a touch input through the screen interface without selecting an auxiliary key of a device capable of inputting by use of an auxiliary key, a key element is processed as input wherein the key element is belonging to the first group allocated to the key corresponding to the divided region selected by the touch, and when it is determined that there is a touch input through the screen interface while the auxiliary key of the device is being selected, a key element is processed as input, wherein the key element is belonging to the second group allocated to the key corresponding to the divided region selected by the touch.

36. The key input interface method of claim 15, wherein the key array consists of three columns and three rows, and in the processing of the key element, when it is determined that there is a touch input through the screen interface by a first input unit of a device having at least two different input units, a key element belonging to the first group allocated in the second column in the second row is processed as input, and when it is determined that there is a stroke input through the screen interface by the first input unit of the device, according to the direction of the stroke, a key element belonging to the first group allocated to one of the keys other than the key in the second column in the second row is processed as input, when it is determined that there is a touch input through the screen interface by a second input unit of the device, a key element belonging to the second group allocated to the second column in the second row is processed as input, and when it is determined that there is a stroke input through the screen interface by the second input unit of the device, according to the direction of the stroke, a key element belonging to the second group allocated to one of the keys other than the key in the second column and second row is processed as input

37. The key input interface method of claim 15, wherein in the processing of the key element, when a divided region of the screen interface is selected based on the time duration of a touch, if it is determined that the touch is made less than a predetermined duration of time, a key element belonging to the first group allocated to the key corresponding to the selected divided region is processed as input, and if it is determined that the touch is made longer than a predetermined duration of time, a key element belonging to the second group allocated to the key corresponding to the selected divided region is processed as input.

38. The key input interface method of claim 15, wherein in the processing of the key element, when a divided region of the screen interface is selected based on the intensity of a touch, if the intensity of the touch is less than a predetermined value, a key element belonging to the first group allocated to the key corresponding to the divided region is processed as input, and if the intensity of the touch is greater than a predetermined value, a key element belonging to the second group allocated to the key corresponding to the divided region is processed as input.

39. A computer readable recording medium having embodied thereon a computer program for executing a method of claim 1.
